(19) United States
(12) Patent Application Publication
(10) Pub. No.: US 2009/0116185 A1
(43) Pub. Date: May 7, 2009

(54) Small form-factor pluggable transceiver module housing

(76) Inventors: Hou-An Su, Keelung City (TW); You-Hua Cai, Zijin County (CN); Chin-Pao Wu, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/979,389

(22) Filed: Nov. 2, 2007

(51) Int. Cl. H05K 7/00; H05K 7/20

(52) U.S. Cl. 361/688; 361/728; 361/747

(57) ABSTRACT

A small form-factor pluggable transceiver module housing includes a metallic casing and a plurality of reinforcing ribs. The metallic casing has a top plate, two side walls, a bottom plate, a plurality of connecting legs, a plurality of locking legs and a plurality of supporting portions. The connecting legs and the supporting portions are formed by means of extending from the lower edges of the two side walls. Each of the connecting legs has an open hole. The reinforcing ribs are each straddling the side wall and the connecting leg. Via this arrangement, the reinforcing ribs can improve the structural strength of the small form-factor pluggable transceiver module housing upon connection to a printed circuit board. The supporting portions can prevent the connecting legs from being damaged due to the excessive force upon connection.

### BACKGROUND OF THE INVENTION

1. Field of the Invention

The present invention relates to a small form-factor pluggable transceiver module housing, and in particular to a small form-factor pluggable transceiver module housing which can be applied to a high-speed data transmission interface.

2. Description of Related Art

Transceiver module is usually used to connect the circuit board of communication lines and other electric modules or apparatuses. Different industrial standards define various interfaces of the connectors between a computer and an external communication apparatus, such as a modem, network interface or other transceiver module. The well-known GBIC (Gigabit Interface Converter) is a transceiver module for performing the communication between a computer and Ethernet, optical fiber channel or other data communication environments.

In order to increase the port density of the transceiver module interconnected with a network apparatus (such as a switch, cable insertion panel, wiring box, I/O ports of a computer), the transceiver module is usually miniaturized. Therefore, the development of a small form-factor pluggable (SFP) transceiver module exactly conforms to this demand. The primary advantage thereof lies in that the volume of the small form-factor pluggable (SFP) transceiver module is merely half the volume of a GBIC transceiver module, thereby allowing the communication system to have a larger density.

The connecting legs of the conventional small form-factor pluggable transceiver module housing are used to fix the small form-factor pluggable transceiver module housing on a printed circuit board. The connecting legs of the small form-factor pluggable transceiver module housing are metallic pieces each of which is formed like a needle eye. The connecting legs extend downwardly from two side walls of the small form-factor pluggable transceiver module housing. Since the thickness of the metallic piece is small, when the small form-factor pluggable transceiver module housing is inserted on the printed circuit board, the connecting legs often break due to the insufficient strength. As a result, the small form-factor pluggable transceiver module housing cannot be mounted on the printed circuit board firmly.

Therefore, in view of the above the drawbacks, the inventor proposes the present invention to overcome the above problems based on his deliberate researches.

### SUMMARY OF THE INVENTION

In view of the above problems, the object of the present invention is to provide a small form-factor pluggable transceiver module housing, in which the connecting legs thereof will not easily suffer damage upon the connection of the small form-factor pluggable transceiver module housing to a printed circuit board.

In order to achieve the above object, the present invention provides a small form-factor pluggable transceiver module housing, which includes: a metallic casing having a top plate, two side walls, a bottom plate, a plurality of connecting legs and a plurality of supporting portions, the two side walls being formed on two opposing sides of the top plate, the bottom plate being connected to the two side walls, the connecting legs and the supporting portions being formed by means of extending from the lower edge of the two side walls, each of the connecting legs having an open hole; and a plurality of reinforcing ribs each straddling the side wall and the connecting leg.

The present invention has the following effect. Since each of the reinforcing ribs straddles the side wall and the connecting leg, the structural strength of the small form-factor pluggable transceiver module housing can be improved upon the connection. The plurality of supporting portions are formed by means of extending from the lower edge of the side wall, so that the connecting legs can be prevented from being damaged due to the excessive force upon the connection.

In order to further understand the characteristics and technical contents of the present invention, the detailed description relating thereto will be made with reference to the accompanying drawings. However, it should be understood that the drawings are illustrative only but not used to limit the present invention.

### BRIEF DESCRIPTION OF THE DRAWINGS

FIG. 1 is a perspective view showing the small form-factor pluggable transceiver module housing of the present invention;

FIG. 1A is an enlarged view showing the portion A in FIG. 1;

FIG. 2A is a front view showing the portion A in FIG. 1 being inserted in a printed circuit board;

FIG. 2B is a cross-sectional view showing portion A in FIG. 1 being inserted in a printed circuit board;

FIG. 3A is a front view showing the portion A in FIG. 1 inserted in a printed circuit board;

FIG. 3B is a cross-sectional view showing portion A in FIG. 1 inserted in a printed circuit board;

FIG. 4 is a perspective view showing the small form-factor pluggable transceiver module housing of the present invention from another viewing angle; and

FIG. 5 is a schematic view showing the combination of the small form-factor pluggable transceiver module housing of the present invention with the printed circuit board.

### DETAILED DESCRIPTION OF THE PREFERRED EMBODIMENTS

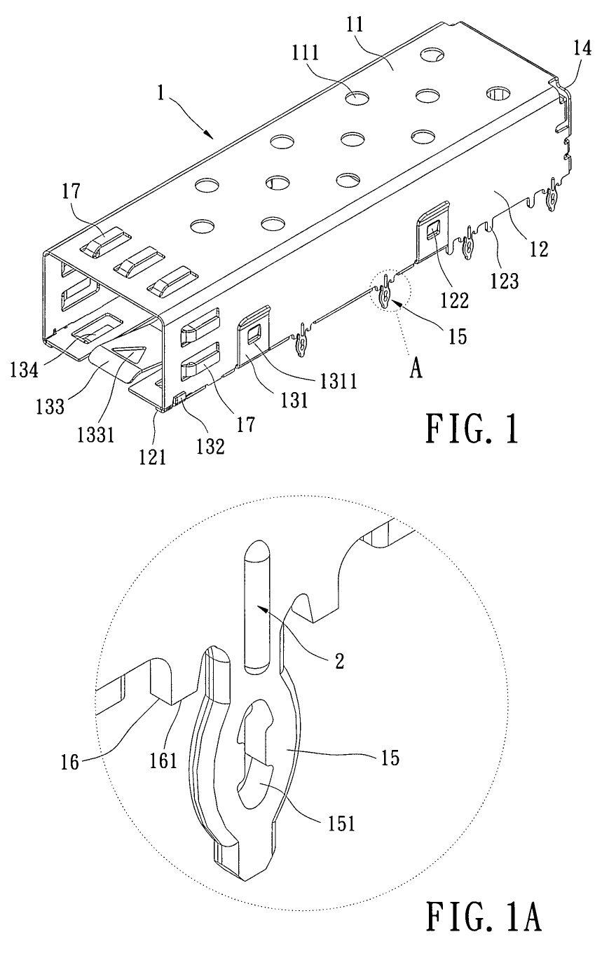

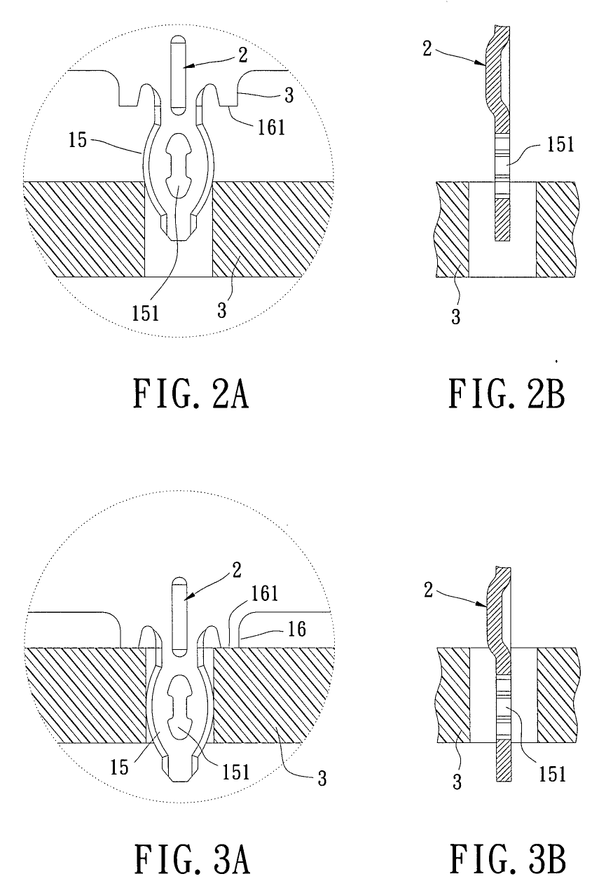

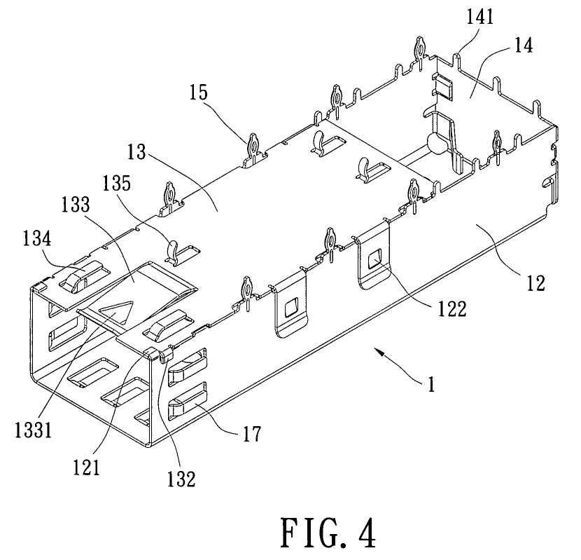

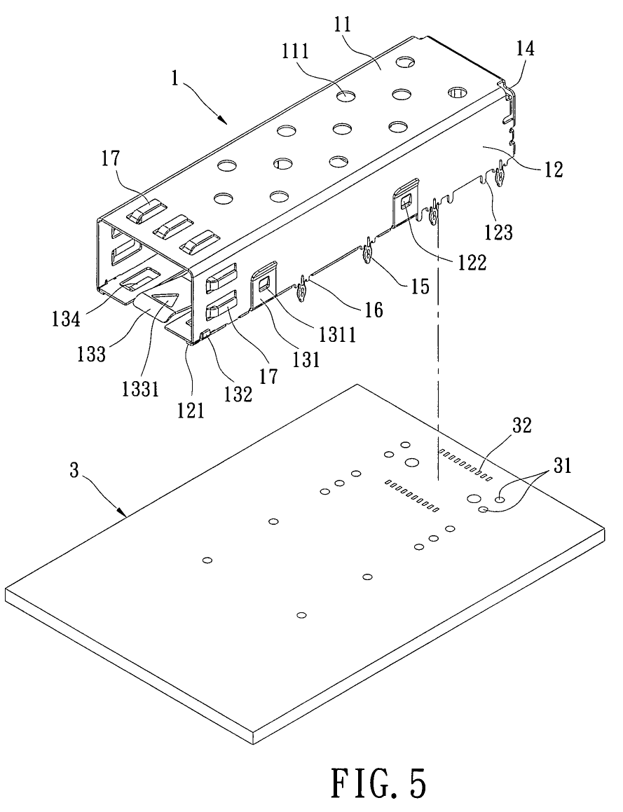

Please refer to FIGS. 1 to 5. The present invention provides a small form-factor pluggable transceiver module housing, which includes a metallic casing 1 and a plurality of reinforcing ribs 2. The metallic casing 1 includes a top plate 11, two side walls 12, a bottom plate 13, a rear cover 14, a plurality of connecting legs 15, a plurality of supporting portions 16 and a plurality of first grounding elastic pieces 17. The top plate 11 is a rectangular metallic plate. The top plate is formed thereon with a plurality of heat-dissipating holes 111 for dissipating the heat of the small form-factor pluggable transceiver module (not shown).

The side wall 12 is a rectangular metallic plate. The two side walls are formed to extend on two opposing sides of the top plate 11. The two side walls 12 have a first locking piece 121, at least one locking block 122 and a plurality of first locking legs 123. The first locking piece 121 is formed by means of extending from the front end of the lower edge of the two side walls. The first locking piece 121 is locked on the bottom plate 13. In the present embodiment, the exterior of the two side walls are provided with four locking blocks 122. Other suitable number of the locking blocks 122 can be used. The plurality of first locking legs 123 is located at the lower edges of the two side walls 12. The first locking legs 123 are substantially in the same plane as the corresponding two side walls 12.

The bottom plate 13 is a rectangular metallic plate. The bottom plate 13 is connected to the lower edges of the two side walls 12. Each of the two opposing sides in the periphery of the bottom plate 13 has at least one elastic piece 131 and a first locking piece 132. In the present embodiment, four elastic pieces 131 extend upwardly from two opposing sides of the bottom plate 13. Other suitable number of the elastic pieces 131 can be used to correspond to that of the locking blocks 122. Each of the four elastic pieces 131 has an opening 1311. The opening 1311 is locked with the locking block 122, so that the bottom plate 13 are connected with the two side walls 12. The two locking pieces 132 are formed by means of extending upwardly from the vicinity of the front end in the periphery of the bottom plate 13. The second locking piece 132 abuts against the first locking piece 121. The second locking piece 132 is locked on the side wall 12.

The front end of the bottom plate 13 has a locking elastic piece 133 and two second grounding elastic pieces 134. The locking elastic piece 133 protrudes inwardly from the front end of the bottom plate 13. The locking elastic piece 133 is formed thereon with a triangular locking port 1331 for locking with the small form-factor pluggable transceiver module. The two second grounding elastic pieces 134 protrude outwardly from the bottom plate 13. The two second grounding elastic pieces 134 are located on both sides of the locking elastic piece 133. The two grounding elastic pieces 134 and the first grounding elastic pieces 17 are brought into contact with an external grounding source (not shown), thereby preventing electromagnetic interference.

In the present embodiment, the bottom plate 13 extends outwardly to form three engaging legs 135. Other suitable number of the engaging legs 135 can be used. The three engaging legs 135 are metallic elastic pieces. The three engaging legs are formed in the middle section and rear end of the bottom plate 13.

The rear cover 14 is also a rectangular metallic plate which extends from the rear end of the top plate 11. The rear cover 14 is connected with the two side walls 12. In the present embodiment, the lower edge of the rear cover 14 extends to form three second locking legs 141. Other suitable number of the second locking legs 141 can be used.

The connecting legs 15 are oval metallic elastic pieces. The connecting legs 15 are formed by means of extending from the lower edge of the two side walls 12. The center of each of the connecting legs 15 is provided with an open hole 151. The open hole 151 allows the connecting leg 15 to be elastically compressed.

The supporting portions 16 are metallic protruding blocks that are formed by means of extending from the lower edges of the two side walls 12. Each of the supporting portions 16 has a supporting surface 161. The supporting portion 16 is adjacent to the connecting leg 15. The length of the supporting portion 16 is smaller than that of the connecting leg 15.

The first grounding elastic pieces 17 are circumferentially provided adjacent to the front end of the metallic casing 1. The first grounding elastic pieces 17 extend outwardly from the metallic casing 1.

The reinforcing ribs 2 are formed into elongated strips. Each of the reinforcing ribs 2 straddles the side wall 12 and the connecting leg 15. Each of the reinforcing ribs 2 connects the side wall 12 and the connecting leg 15.

When the metallic casing 1 is mounted, the connecting legs 15 and the first locking legs 123 of the two side walls 12 are inserted in corresponding through holes 31 of a printed circuit board 3. The second locking legs 141 of the rear cover 14 are also inserted in the corresponding through holes 31 of the printed circuit board 3, so that the metallic casing 1 is fixed on the printed circuit board 3. The printed circuit board further has a plurality of welding points 32 for being welded to an electric connector. The reinforcing rib 2 straddles the side wall 12 and the connecting leg 15, thereby improving the structural strength of the connecting leg 15. The supporting surfaces 161 of the supporting portions 16 and the engaging legs 135 of the bottom plate 13 abut on the printed circuit board 3, so that the connecting legs 15 will not get damaged due to the excessive force in mounting. Therefore, the metallic casing 1 can be firmly mounted on the printed circuit board 3.

Although the present invention has been described with reference to the foregoing preferred embodiment, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A small form-factor pluggable transceiver module housing, comprising;
a metallic casing having a top plate, two side walls, a bottom plate, a plurality of connecting legs and a plurality of supporting portions, the two side walls being formed on two opposing sides of the top plate, the bottom plate being connected to the two side walls, the connecting legs and the supporting portions being formed by means of extending from lower edges of the two side walls, each of the connecting legs having an open hole; and
a plurality of reinforcing ribs each straddling the side wall and the connecting leg.

2. The small form-factor pluggable transceiver module housing according to claim 1, wherein each of the top plate and the two side walls has a plurality of first grounding elastic pieces, the top plate has a plurality of heat-dissipating holes, and the first grounding elastic pieces are provided adjacent to the front end of the metallic casing.

3. The small form-factor pluggable transceiver module housing according to claim 1, wherein the exterior of each of the two side walls is provided with at least one locking block.

4. The small form-factor pluggable transceiver module housing according to claim 3, wherein two opposing sides of the bottom plate extend upwardly to form at least one elastic piece, the elastic piece has an opening, and the opening is locked with the locking block.

5. The small form-factor pluggable transceiver module housing according to claim 1, wherein the front end of the lower edge of the side wall extends to form a first locking piece, and the first locking piece is locked on the bottom plate.

6. The small form-factor pluggable transceiver module housing according to claim 5, wherein each of the two opposing sides on the periphery of the bottom plate has a second locking piece, the second locking piece is locked on the two side walls, and the second locking piece abuts against the first locking piece.

7. The small form-factor pluggable transceiver module housing according to claim 1, wherein the front end of the bottom plate has an inwardly-protruding locking elastic piece and two outwardly-protruding second grounding elastic pieces, and the two second grounding elastic pieces are located on both sides of the locking elastic piece.

8. The small form-factor pluggable transceiver module housing according to claim 1, wherein the rear end of the metallic casing has a rear cover, and the rear cover is formed by means of extending from the rear end of the top plate.

9. The small form-factor pluggable transceiver module housing according to claim 8, wherein the lower edges of the two side walls extend to form a plurality of first locking legs, and the lower edge of the rear cover extends to form a plurality of second locking legs.

10. The small form-factor pluggable transceiver module housing according to claim 1, wherein the bottom plate extends outwardly to form a plurality of engaging legs.
